(19) United States
(12) Patent Application Publication
(10) Pub. No.: US 2009/0068850 A1
(43) Pub. Date: Mar. 12, 2009

(54) Method of Fabricating Flash Memory Device

(75) Inventors: Jae Hyoung Koo, Seoul (KR); Kwon Hong, Seongnam-si (KR); Jae Hong Kim, Seongnam-si (KR); Eun Shil Park, Namyangju-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 12/147,802

(22) Filed: Jun. 27, 2008

(30) Foreign Application Priority Data
Sep. 7, 2007 (KR) 10-2007-0090895

(51) Int. Cl. H01L 21/283

(52) U.S. Cl. 438/771; 257/E21.159

(57) ABSTRACT

The present invention relates generally to a method of fabricating a flash memory device. The method includes forming a tunnel dielectric layer on a semiconductor substrate using a plasma oxidization process. The tunnel dielectric layer is formed using the plasma oxidation process employing Ar and O₂ gases, therefore, defect charges can be prevented from being created due to dangling bonds such as Si—H. Accordingly, the shift of the threshold voltage (Vth) of a device can be reduced and cycling and charge retention characteristics can be improved.

### CROSS-REFERENCE TO RELATED APPLICATION

Priority to Korean patent application number 10-2007-090895, filed on Sep. 7, 2007, the disclosure of which is incorporated by reference in its entirety, is claimed.

### BACKGROUND OF THE INVENTION

The present invention relates generally to a method of fabricating a flash memory device and, more particularly, to a method of fabricating a flash memory device that can improve cycling and charge retention characteristics.

A flash memory type device of semiconductor devices is a non-volatile memory device, which can retain information stored in a memory cell when power is off and which can be electrically erased at high speed with it being mounted in a circuit board. Recently, much research has focused on the flash memory device because of its advantageous structure in higher integration.

A unit cell of this flash memory device has a structure in which a tunnel dielectric layer (e.g., a tunnel oxide layer), a floating gate, a dielectric layer and a control gate are sequentially stacked over an active region of a semiconductor substrate. Of them, a thin film of the tunnel oxide layer itself serves as a passage along which data is moved, unlike the gate insulating layer of a general transistor. Thus, the tunnel oxide layer requires very excellent thin film characteristics.

In NAND flash devices, both program and erase operations employ F—N tunneling. If numerous program and erase operations are repeatedly executed, the tunnel oxide layer is degraded. This makes it impossible for the tunnel oxide layer to perform its functions. Thus, the tunnel oxide layer is formed as thin as possible so as to improve the program speed characteristic, but nitrogen is injected into the thin film in order to prevent degradation of the thin film characteristics.

A general method of injecting nitrogen into the tunnel oxide layer includes a thermal oxidation process such as a wet oxidation process or a radical oxidation process. After a pure silicon oxide (SiO₂) layer is grown using this thermal oxidation process, a silicon oxynitride (SiON) layer is formed through annealing employing N₂O, NO or NH₃ gas. Here, most of the injected nitrogen is accumulated at the interface of a semiconductor substrate (Si) and the SiO₂ layer. The accumulated nitrogen substitutes interface trap charges, which are inevitably generated at the semiconductor substrate (Si) and the silicon oxide (SiO₂) layer, thereby improving the interface characteristic of the tunnel oxide layer.

The tunnel oxide layer is generally grown at a high temperature of 800 degrees Celsius or more using a wet oxidization process employing H₂O, or using a radical oxidization process of a high temperature and a low pressure employing H₂ and O₂. Thus, defect bonds (that is, dangling bonds) of a hydrogen base such as Si—H are created under the influence of hydrogen, so defect charges trapped at a deep level in the tunnel oxide layer are increased. Accordingly, there are problems in view of reliability in cycling and charge retention characteristics, etc.

Furthermore, the wet oxidization process and the radical oxidization process require a process temperature of 800 degrees Celsius or more. This increases the thermal budget and also causes boron (B), etc. to be diffused externally. Furthermore, a problem arises because the film quality of the tunnel oxide layer is degraded in a subsequent high-temperature process.

### BRIEF SUMMARY OF THE INVENTION

The present invention is directed towards a method of fabricating a flash memory device, which can improve cycling and charge retention characteristics by forming a tunnel dielectric layer using a plasma oxidation process.

A method of fabricating a flash memory device in accordance with one embodiment includes forming a tunnel dielectric layer on a semiconductor substrate using a plasma oxidization process.

The plasma oxidization process can be performed using Ar and O₂ gases. The plasma oxidization process can be performed in a temperature range of 200 to 500 degrees Celsius. The plasma oxidization process can be performed under a pressure in a range of 0.1 to 10 torr by using power in a range of 5 kW and below. The plasma oxidization process can be performed to generate plasma using direct current (DC) discharge, radio frequency (RF) discharge or microwave.

The tunnel dielectric layer can be formed to a thickness in a range of 20 to 100 angstrom. The plasma oxidization process can be performed by further using H₂ gas, which can be used in an amount of 1% or less based on a total amount of gas, in order to increase the growth rate of the tunnel dielectric layer.

After the tunnel dielectric layer is formed, nitrogen can be accumulated at the interface of the semiconductor substrate and the tunnel dielectric layer. The nitrogen can be accumulated using an annealing process employing N₂O or NO gas. For example, the nitrogen can be accumulated by performing annealing using N₂O gas and then performing a N₂ or O₂ purge. The nitrogen can also be accumulated by performing annealing using NO gas and then performing an O₂ purge. At the time of the annealing employing N₂O gas, a pre-activation chamber (PAC) can be used.

After nitrogen is accumulated at the interface of the semiconductor substrate and the tunnel dielectric layer, O₃ treatment can be performed. After the tunnel dielectric layer is formed, N₂ or O₂ annealing can be performed.

### BRIEF DESCRIPTION OF THE DRAWINGS

FIGS. 1a and 1b are sectional views illustrating a method of fabricating a flash memory device in accordance with an embodiment of the disclosure herein.

### DESCRIPTION OF SPECIFIC EMBODIMENTS

A specific embodiment will be described with reference to the accompanying drawings. However, the present invention is not limited to the disclosed embodiment, but may be implemented in various manners. The present invention is defined by the category of the claims.

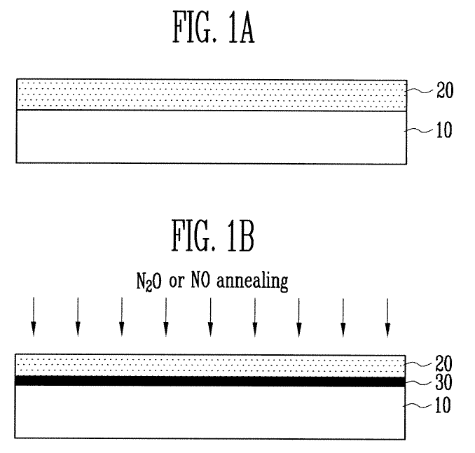

FIGS. 1a and 1b are sectional views illustrating a method of fabricating a flash memory device in accordance with an embodiment of the disclosure herein.

Referring to FIG. 1a, a semiconductor substrate 10 having a well area (not shown) formed therein is provided. The well area can have a triple structure. In one embodiment, the well area is formed by forming a screen oxide layer (not shown) on the semiconductor substrate 10 and then performing a well ion implantation process and a threshold voltage ion implantation process.

After the screen oxide layer is removed, a tunnel dielectric layer 20 is formed on the semiconductor substrate 10. The tunnel dielectric layer 20 can be formed from silicon oxide (SiO₂). The tunnel dielectric layer 20 can be formed using a plasma oxidation process.

More specifically, the plasma oxidization process can be performed using Ar and O₂ gases in a temperature range of 200 to 500 degrees Celsius under a pressure in a range of 0.1 to 10 torr by using power in a range of 5 kW and below.

The plasma oxidization process employs the principle of generating plasma using direct current (DC) discharge, radio frequency (RF) discharge or microwave. Here, the tunnel dielectric layer 20 can be formed to a thickness in a range of 20 to 100 angstrom.

As described above, if the tunnel dielectric layer 20 is formed by the plasma oxidization process using Ar and O₂ gases without using hydrogen (H), defect bonds (that is, dangling bonds) of a hydrogen base, such as Si—H within the tunnel dielectric layer 20, are not created, so the occurrence of defect charges trapped at a deep level can be prohibited. Thus, since the characteristics of the tunnel dielectric layer 20 are prevented from being degraded, the shift of the threshold voltage (Vth) can be reduced and the cycling and charge retention characteristics can be improved. Thus, preferably the tunnel dielectric layer is formed by a plasma oxidation process essentially free of or free of hydrogen gas.

Further, since the tunnel dielectric layer 20 is formed by the plasma oxidization process, a more dense thin film can be obtained and the film quality of the tunnel dielectric layer 20 can be prevented from being degraded in a subsequent high-temperature process.

Further, since the tunnel dielectric layer 20 is formed by the plasma oxidization process at a low temperature of 500 degrees Celsius or less, a bird's beak phenomenon in which an oxide layer is grown at both ends of the tunnel dielectric layer 20 due to high temperatures can be prevented or reduced. In addition, boron (B) can be prevented from being diffused externally and degradation of the film quality can be prevented.

In the plasma oxidization process for forming the tunnel dielectric layer 20 as described above, it is preferred that hydrogen (H) not be used so as to prevent dangling bonds from being created. However, in order to increase the growth rate of the tunnel dielectric layer 20, H₂ gas may optionally be additionally used. However, a very small amount of H₂ gas is preferably used. The H₂ gas, if used, preferably may be used in an amount of 1% or less based on the total amount of the gas, as compared to the conventional 10%.

Referring to FIG. 1b, a process of accumulating nitrogen at the interface of the semiconductor substrate 10 and the tunnel dielectric layer 20 is further performed. The process for accumulating nitrogen at the interface can be performed using an annealing process employing N₂O or NO gas. Here, the annealing process can include performing annealing employing N₂O gas and then performing a N₂ or O₂ purge, or performing annealing employing NO gas and then performing an O₂ purge. At the time of annealing employing N₂O gas, a pre-activation chamber (PAC) is used.

Accordingly, a nitrogen-containing insulating layer 30 in which nitrogen is accumulated at the interface of the semiconductor substrate 10 and the tunnel dielectric layer 20 is formed.

As described above, the nitrogen-containing insulating layer 30 in which nitrogen is accumulated at the interface of the semiconductor substrate 10 and the tunnel dielectric layer 20 through annealing employing N₂O or NO gas substitutes interface trap charges, which are inevitably generated at the interface of the semiconductor substrate 10 and the tunnel dielectric layer 20. Thus, the interface characteristic of the tunnel dielectric layer 20 can be improved.

Further, after nitrogen is accumulated at the interface of the semiconductor substrate 10 and the tunnel dielectric layer 20, O₃ treatment may be further performed in order to mitigate electrical stress of the nitrogen-containing insulating layer 30, increase oxygen density, and improve surface roughness.

After the tunnel dielectric layer 20 is formed, annealing employing N₂ or O₂ may be further carried out in order to densify the film.

Although not shown in the drawings, a polysilicon layer for a floating gate can be formed on the tunnel dielectric layer 20 and subsequent processes can then be performed to form a unit cell of a flash memory device (e.g., formation of a top dielectric layer and control gate).

As described above, the present invention preferably has one or more of the following advantages.

First, since the tunnel dielectric layer is formed using a plasma oxidation process employing Ar and O₂ gases, defect charges can be reduced or prevented from being created due to dangling bonds such as Si—H. Accordingly, the shift of the threshold voltage (Vth) of a device can be reduced and cycling and charge retention characteristics can be improved.

Second, since the tunnel dielectric layer is formed using a plasma oxidization process, a more dense thin film can be obtained. Accordingly, the film quality of the tunnel oxide layer can be prevented from being degraded in a subsequent high-temperature process.

Third, since the tunnel dielectric layer is formed using the plasma oxidization process at a temperature of 500 degrees Celsius or less, a bird's beak phenomenon of the tunnel dielectric layer due to high temperatures can be improved and boron (B) can be inhibited or prevented from being diffused externally. Accordingly, degradation of the film quality can be prevented.

Fourth, nitrogen is accumulated at the interface of the semiconductor substrate and the tunnel dielectric layer by performing annealing employing N₂O or NO gas in order to substitute interface trap charges. Thus, an interface characteristic of the tunnel oxide layer can be improved.

Fifth, since the film quality of the tunnel dielectric layer is improved, reliability of a device made using the resulting structure can be improved.

The embodiment disclosed herein allows a person skilled in the art to easily implement the present invention, and the person skilled in the part may implement the present invention in various ways. Therefore, the scope of the present invention is not limited by or to the embodiment as described above, and should be construed to be defined only by the appended claims and their equivalents.

What is claimed is:

1. A method of fabricating a flash memory device comprising:
forming a tunnel dielectric layer on a semiconductor substrate using a plasma oxidization process.

2. The method of claim 1, further comprising performing the plasma oxidization process using Ar and O₂ gases.

3. The method of claim 1, further comprising performing the plasma oxidization process in a temperature range of 200 to 500 degrees Celsius.

4. The method of claim 1, further comprising performing the plasma oxidization process under a pressure in a range of 0.1 to 10 torr and using power in a range of 5 kW and below.

5. The method of claim 1, further comprising performing the plasma oxidization process using direct current (DC) discharge, radio frequency (RF) discharge or microwave to generate plasma.

6. The method of claim 1, further comprising forming the tunnel dielectric layer to a thickness in a range of 20 to 100 angstrom.

7. The method of claim 1, further comprising performing the plasma oxidization process using H₂ gas in an amount of 1% or less based on a total amount of gas in order to increase the growth rate of the tunnel dielectric layer.

8. The method of claim 1, further comprising accumulating nitrogen at an interface of the semiconductor substrate and the tunnel dielectric layer after the tunnel dielectric layer is formed.

9. The method of claim 8, further comprising accumulating nitrogen using an annealing process employing N₂O or NO gas.

10. The method of claim 9, further comprising performing the annealing process employing N₂O gas and then performing a N₂ or O₂ purge.

11. The method of claim 9, further comprising performing annealing employing NO gas and then performing an O₂ purge.

12. The method of claim 9, further comprising performing the annealing process employing N₂O gas and using a pre-activation chamber (PAC).

13. The method of claim 8, further comprising performing an O₃ treatment, after nitrogen is accumulated at the interface of the semiconductor substrate and the tunnel dielectric layer.

14. The method of claim 1, further comprising performing N₂ or O₂ annealing after the tunnel dielectric layer is formed.
